(19) United States
(12) Patent Application Publication
(10) Pub. No.: US 2023/0185181 A1
(43) Pub. Date: Jun. 15, 2023

(54) REFLECTION-TYPE MASK, REFLECTION-TYPE MASK BLANK, AND METHOD FOR MANUFACTURING REFLECTION-TYPE MASK

(71) Applicant: AGC Inc., Tokyo (JP)

(72) Inventor: Hiroyoshi TANABE, Tokyo (JP)

(73) Assignee: AGC Inc., Tokyo (JP)

(21) Appl. No.: 18/166,715

(22) Filed: Feb. 9, 2023

Related U.S. Application Data
(63) Continuation of application No. PCT/JP2021/031257, filed on Aug. 25, 2021.

(30) Foreign Application Priority Data
Sep. 4, 2020 (JP) 2020-148984

(51) Int. Cl. G03F 1/24; G03F 1/26; G03F 1/54

(52) U.S. Cl. CPC G03F 1/24; G03F 1/26; G03F 1/54

(57) ABSTRACT

A reflective mask blank includes a substrate, and a multilayer reflective film configured to reflect EUV light, a phase shift film configured to shift a phase of the EUV light, and a semi-light-shielding film configured to shield the EUV light, which are formed on the substrate in this order. A reflectance at a wavelength of 13.5 nm when a surface of the semi-light-shielding film is irradiated with the EUV light is less than 7%. A reflectance at a wavelength of 13.5 nm when a surface of the phase shift film is irradiated with the EUV light is 9% or more and less than 15%.

### CROSS-REFERENCE TO RELATED APPLICATIONS

This is a bypass continuation of International Patent Application No. PCT/JP2021/031257, filed on Aug. 25, 2021, which claims priority to Japanese Patent Application No. 2020-148984, filed on Sep. 4, 2020. The contents of these applications are hereby incorporated by reference in their entireties.

### TECHNICAL FIELD

The present invention relates to a reflective mask for use in an extreme ultra violet (EUV) exposure process in semiconductor production, a reflective mask blank that is an unpatterned plate of the reflective mask, and a method for producing a reflective mask.

### BACKGROUND ART

In the related art, ultraviolet light with a wavelength of 365 nm to 193 nm has been used as a light source for an exposure apparatus for use in semiconductor production. The shorter the wavelength, the higher the resolution of the exposure apparatus. Therefore, in recent years, an exposure apparatus using EUV light with a center wavelength of 13.53 nm as a light source has been put to practical use.

The EUV light is easily absorbed by many substances, and a refractive optical system cannot be used in the exposure apparatus. Therefore, in EUV exposure, a reflective optical system and a reflective mask are used.

In the reflective mask, a multilayer reflective film that reflects EUV light is formed on a substrate, and an absorber film that absorbs EUV light is formed in a pattern form on the multilayer reflective film.

The EUV light incident on the reflective mask is absorbed by the absorber film and reflected by the multilayer reflective film. The EUV light reflected by the multilayer reflective film forms an image on the surface of an exposure material (wafer coated with a resist) through a reduction projection optical system of the exposure apparatus.

Since the absorber film is formed in a pattern on the multilayer reflective film, the EUV light incident on the reflective mask due to the reflective optical system of the exposure apparatus is reflected at portions without the absorber film (openings) and absorbed at portions with the absorber film (non-openings). Accordingly, the openings in the absorber film are transferred as a mask pattern onto the surface of the exposure material.

In EUV lithography, EUV light is usually incident on a reflective mask from an approximately 6° oblique direction and reflected in an approximately 6° oblique direction.

An exposure region in the reflective mask is determined by a mask blade installed in the exposure apparatus. The mask blade is installed several millimeters above the reflective mask so as not to come into contact with the reflective mask. A non-exposure region in the reflective mask is shielded by the mask blade.

However, since there is a gap with several millimeters between the reflective mask and the mask blade, light diffraction occurs and light leaks from adjacent shots. In order to prevent light leakage from adjacent shots, the non-exposure region in the reflective mask, or at least an exposure frame portion, is required to have a reflectance of less than 0.5% at a wavelength of 13.5 nm when the surface is irradiated with EUV light (hereinafter, in this description, may be referred to as an “EUV light reflectance”).

In order to make the EUV light reflectance of the non-exposure region in the reflective mask less than 0.5%, Patent Literature 1 proposes a reflective mask shown in FIG. 2A and FIG. 2B.

In a reflective mask 30 shown in FIG. 2A and FIG. 2B, a multilayer reflective film 32 that reflects EUV light, a protective film 33 for the multilayer reflective film 32, and an absorber film 36 that absorbs EUV light are formed on a substrate 31 in this order. In an exposure region 100 in the reflective mask 30, the absorber film 36 is formed in a pattern. In a non-exposure region 200 in the reflective mask 30, a light shielding film 37 is formed on the absorber film 36.

However, in order to make the reflectance of the non-exposure region 200 less than 0.5%, the total film thickness of the absorber film 36 and the light shielding film 37 is required to be 70 nm or more. In this way, the film thickness is large, making it difficult to etch fine patterns in a chip, so that this technique is not currently in practical use.

In order to make the EUV light reflectance of the exposure frame portion in the reflective mask less than 0.5%, Patent Literature 1 proposes a reflective mask shown in FIG. 3A and FIG. 3B.

In a reflective mask 40 shown in FIG. 3A and FIG. 3B, a multilayer reflective film 42 that reflects EUV light, a protective film 43 for the multilayer reflective film 42, and an absorber film 46 that absorbs EUV light are formed on a substrate 41 in this order. In the exposure region 100 in the reflective mask 40, the absorber film 46 is formed in a pattern. In an exposure frame region 300 between the exposure region 100 and the non-exposure region 200 in the reflective mask 30, the multilayer reflective film 42, the protective film 43, and the absorber film 46 are removed by etching to expose a surface of the substrate 41. Since the width of the exposure frame is as wide as several hundred gm, etching can be performed using a thick film resist until the surface of the substrate 41 is exposed. The EUV light reflectance of the surface of the substrate 41 is sufficiently low as less than 0.1%. Therefore, the exposure frame region 300 is almost completely shielded. Therefore, this technique is currently in practical use.

In the related art, a tantalum-based material containing tantalum is used for the absorber film An absorber film containing a tantalum-based material is used under the condition of a binary-type reflective mask, and usually has an EUV light reflectance of 2% or less.

In recent years, by adjusting the EUV light reflectance and the phase shift amount of EUV light, development of a reflective mask using a phase shift effect has been advanced. By using the reflective mask using the phase shift effect, the contrast of the optical image on the wafer is improved and the exposure margin is increased.

In the case of a transmissive phase shift mask for use in ultraviolet light exposure, the transmittance of the phase shift film is high in order to obtain a phase shift effect, and the overlapping light of adjacent shots is a problem as in the case of the reflective mask. In a phase shift mask in Patent Literature 2, by covering the exposure frame with a light shielding film, the overlapping light of adjacent shots is prevented, as the reflective mask 30 shown in FIG. 2A and FIG. 2B.

In addition to the chip, there are scribe lines in the exposure region for cutting the chip in a final step of semiconductor production. Alignment marks as shown in FIG. 4A and overlay marks as shown in FIG. 4B are disposed within the scribe lines. The alignment marks are used for alignment between the exposure apparatus and the wafer, and the overlay marks are used for overlay error measurement between a lower layer pattern P₂ and an upper layer pattern P₁. The line width of these marks is on the order of several μm to several tens of μm, which is much larger than a fine pattern on the order of several tens of nm in the chip.

In the transmissive phase shift mask, when the transmittance of the phase shift film is increased to obtain the phase shift effect, side lobes of a large pattern having a large line width such as alignment marks and overlay marks become large, and transfer onto the resist on the wafer becomes a problem.

In order to solve this problem, in the transmissive phase shift mask for use in ultraviolet light, a light shielding film is also provided on alignment marks and overlay marks within scribe lines, like a phase shift mask in Patent Literature 3.

### CITATION LIST

### Patent Literature

Patent Literature 1: JP2009-141223A

Patent Literature 2: JPH06-282063A

Patent Literature 3: JP2942816B

### SUMMARY OF INVENTION

### Technical Problem

In the case of a reflective phase shift mask for use in EUV exposure, when the EUV light reflectance of the phase shift film is increased in order to enhance the phase shift effect, side lobes of a large pattern such as alignment marks and overlay marks within the scribe lines also become large, and transfer onto the resist on the wafer also becomes a problem.

However, in the case of the reflective phase shift mask for use in EUV exposure, when the light shielding film 37 having a large film thickness as in the reflective mask 30 shown in FIG. 2A and FIG. 2B is formed on the scribe line, pattern formation by etching becomes difficult. In addition, as the reflective mask 40 shown in FIG. 3A and FIG. 3B, it is difficult to perform etching in a portion to be shielded from light to expose the surface of the substrate due to alignment marks and overlay marks within the scribe lines.

An object of the present invention to provide a reflective mask blank from which a reflective mask with prevented transfer of side lobes of a large pattern can be produced, a reflective mask, and a method for producing a reflective mask.

### Solution to Problem

As a result of intensive studies aimed at solving the above problems, the inventors of the present invention have found that the above problems can be solved by the following configuration.

[1] A reflective mask blank including: a substrate; and a multilayer reflective film configured to reflect EUV light, a phase shift film configured to shift a phase of the EUV light, and a semi-light-shielding film configured to shield the EUV light, which are formed on the substrate in this order, in which

a reflectance at a wavelength of 13.5 nm when a surface of the semi-light-shielding film is irradiated with the EUV light is less than 7%, and

a reflectance at a wavelength of 13.5 nm when a surface of the phase shift film is irradiated with the EUV light is 9% or more and less than 15%.

[2] The reflective mask blank according to [1], in which the semi-light-shielding film has a film thickness of 3 nm or more and 10 nm or less.

[3] The reflective mask blank according to [1] or [2], in which a phase shift amount of the EUV light of the phase shift film is 210 degrees or more and 250 degrees or less.

[4] The reflective mask blank according to any one of [1] to [3], in which the phase shift film is made of a Ru-based material containing Ru.

[5] The reflective mask blank according to any one of [1] to [4], in which the semi-light-shielding film is made of a Cr-based material containing Cr or a Ta-based material containing Ta.

[6] The reflective mask blank according to any one of [1] to [5], in which the phase shift film has a film thickness of 20 nm or more and 60 nm or less.

[7] The reflective mask blank according to any one of [1] to [6], further including: a protective film for the multilayer reflective film between the multilayer reflective film and the phase shift film.

[8] A reflective mask including: a pattern having a chip region and a scribe line region, which is formed on the semi-light-shielding film and the phase shift film of the reflective mask blank according to any one of [1] to [7], in which

the chip region in the pattern does not have the semi-light-shielding film on the phase shift film, and the scribe line region in the pattern has the semi-light-shielding film on the phase shift film.

[9] The reflective mask according to [8], in which the pattern has an exposure frame region, the exposure frame region does not have the multilayer reflective film, the phase shift film, and the semi-light-shielding film, and a surface of the substrate is exposed.

A method for producing a reflective mask, including:

a step of forming a pattern having a chip region and a scribe line region on the semi-light-shielding film and the phase shift film of the reflective mask blank according to any one of [1] to [7];

a step of removing the semi-light-shielding film in the chip region; and

a step of etching the semi-light-shielding film, the phase shift film, and the multilayer reflective film in an exposure frame region until a surface of the substrate is exposed.

### Advantageous Effects of Invention

The reflective mask according to the present invention can prevent transfer of side lobes of a large pattern. According to the reflective mask blank and the method for producing a reflective mask of the present invention, a reflective mask with prevented transfer of side lobes of a large pattern can be produced.

### BRIEF DESCRIPTION OF DRAWINGS

FIG. 1 is a schematic cross-sectional view of one configuration example of a reflective mask blank according to the present invention.

FIG. 2A and FIG. 2B show diagrams showing one configuration example of a reflective mask described in Patent Literature 1; FIG. 2A is a plan view and FIG. 2B is a schematic cross-sectional view.

FIG. 3A and FIG. 3B show diagrams showing another configuration example of the reflective mask described in Patent Literature 1; FIG. 3A is a plan view and FIG. 3B is a schematic cross-sectional view.

FIG. 4A and FIG. 4B are diagrams showing one configuration example of alignment marks; FIG. 4B is a diagram showing one configuration example of overlay marks.

FIG. 5A and FIG. 5B are graphs comparing phase shift films having different alloy proportions of Ru and Cr; FIG. 5A is a graph showing a relationship between a film thickness of a phase shift film and an EUV light reflectance, and FIG. 5B is a graph showing a relationship between the film thickness of the phase shift film and a phase shift amount of EUV light.

FIG. 6 is a diagram showing a mask pattern used for exposure simulation.

FIG. 7 is a diagram showing a relationship between the film thickness of the phase shift film and a NILS for phase shift films having different alloy proportions of Ru and Cr.

FIG. 8 is a diagram showing a relationship between the EUV light reflectance and a maximum NILS.

FIG. 9 is a cross-sectional view of light intensity on a wafer having a 22 nm dense hole pattern as the mask pattern used in the exposure simulation.

FIG. 10A and FIG. 10B are enlarged views around a corner of the pattern HP used in the exposure simulation; FIG. 10B is a diagram showing a light intensity distribution on the wafer around the corner of the pattern HP.

FIG. 11 is a diagram showing a relationship between the EUV light reflectance and side lobe light intensity.

FIG. 12 is a graph showing a relationship between a film thickness of a CrN film and the EUV light reflectance when the CrN film is provided as a semi-light-shielding film on a Ru80Cr20 alloy phase shift film having a thickness of 45 nm.

FIG. 13A and FIG. 13B show diagrams showing one configuration example of a reflective mask according to the present invention; FIG. 13A is a plan view, and FIG. 13B is a schematic cross-sectional view.

FIG. 14A to FIG. 14F show diagrams showing a procedure of producing a reflective mask 20 shown in FIG. 13A and FIG. 13B.

FIG. 15 is a schematic cross-sectional view of a reflective mask blank in Example 1.

FIG. 16 is a diagram showing a relationship between a film thickness of a TaON film and the EUV light reflectance in Example 3.

### DESCRIPTION OF EMBODIMENTS

In order to investigate a phase shift effect of a reflective mask, exposure simulation has been performed by using an alloy of Ru and Cr as the material of a phase shift film and changing the alloy ratio of Ru and Cr to change a refractive index and an absorption coefficient.

Table 1 shows a refractive index n and an absorption coefficient k of alloys of Ru and Cr. In the table, numbers attached to Ru and Cr indicate alloy ratios (atomic ratios). In the table, Ru described at the top is a metal film of Ru, and Cr described at the bottom is a metal film of Cr.

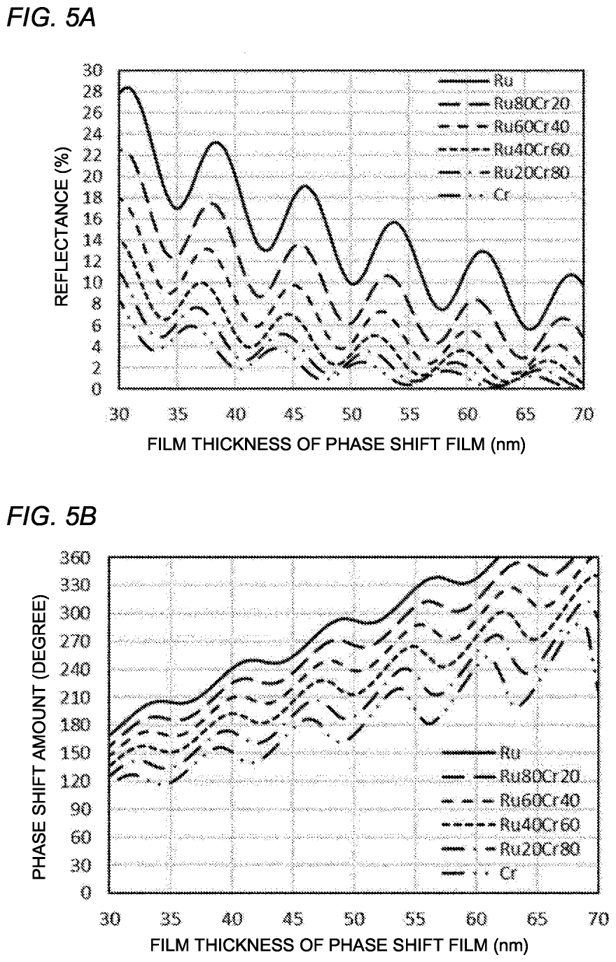

FIG. 5A and FIG. 5B are a graph comparing phase shift films having different alloy proportions of Ru and Cr. FIG. 5A is a graph showing a relationship between a film thickness of a phase shift film and an EUV light reflectance, and FIG. 5B is a graph showing a relationship between the film thickness of the phase shift film and a phase shift amount of EUV light. As shown in FIG. 5A and FIG. 5B, depending on the alloy ratio, the EUV light reflectance and the phase shift amount of the EUV light greatly change. Therefore, the phase shift effect also differs greatly depending on the alloy material used for the phase shift film.

TABLE 1

| | n | k |
|---|---|---|
| Ru | 0.893 | 0.016 |
| Ru80Cr20 | 0.9008 | 0.0206 |
| Ru60Cr40 | 0.9086 | 0.0252 |
| Ru40Cr60 | 0.9164 | 0.0298 |
| Ru20Cr80 | 0.9242 | 0.0344 |
| Cr | 0.932 | 0.039 |

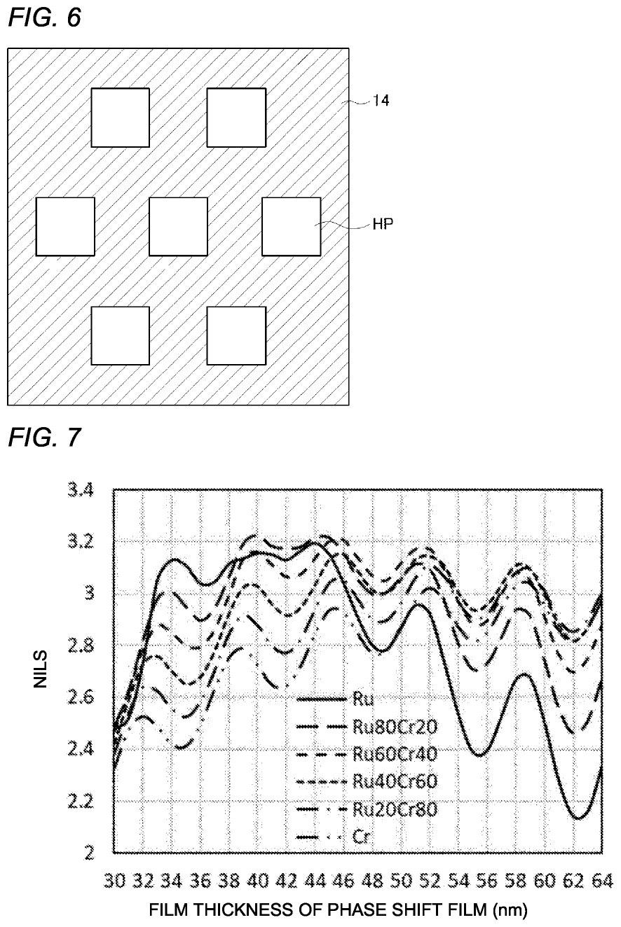

Optical conditions for the exposure simulation include a NA of 0.33 and annular illumination of a 0.6/0.3. A dense hole pattern (HP) having a critical dimension (CD) of 22 nm shown in FIG. 6 is used as the mask pattern. FIG. 7 shows the result of the exposure simulation at this time. FIG. 7 is a diagram showing a relationship between the film thickness of the phase shift film and a NILS for phase shift films having different alloy proportions of Ru and Cr. The larger the normalized image log slope (NILS), the higher the phase shift effect. The NILS depends on the thickness of the phase shift film, and the film thickness at which the NILS is maximized differs depending on an alloy material used for the phase shift film.

Table 2 shows the maximum NILS values of phase shift films having different alloy proportions of Ru and Cr, and the film thickness, the EUV light reflectance, and the phase shift amount at this time.

TABLE 2

| | | Film | | |
|---|---|---|---|---|
| | Maximum | thickness | Reflectance | Phase shift |
| | NILS | (nm) | (%) | amount (deg.) |
| Ru | 3.19 | 44 | 15.3 | 247 |
| Ru80Cr20 | 3.21 | 45 | 13.3 | 237 |
| Ru60Cr40 | 3.21 | 46 | 9.1 | 234 |
| Ru40Cr60 | 3.15 | 46 | 5.8 | 218 |
| Ru20Cr80 | 3.11 | 52 | 3.5 | 217 |
| Cr | 3.04 | 59 | 1.6 | 225 |

In all cases, the phase shift amount of the EUV light is 217 degrees to 247 degrees, which is deviated from the optimum value of 180 degrees for the phase shift amount in ultraviolet light exposure. This is because, in the case of a reflective mask for use in EUV exposure, the phase shift film is thick and a three-dimensional effect of the mask cannot be ignored. The three-dimensional effect of the mask means that the three-dimensional structure of the pattern of the phase shift film has various influences on the projected image of the mask pattern on the wafer.

FIG. 8 is a diagram showing a relationship between the EUV light reflectance and the maximum NILS. As shown in FIG. 8, the maximum NILS increases as the EUV light reflectance increases. However, when the EUV light reflectance becomes too high, the maximum NILS decreases. As seen from FIG. 8, the optimum value of the EUV light reflectance is 9% or more and less than 15%.

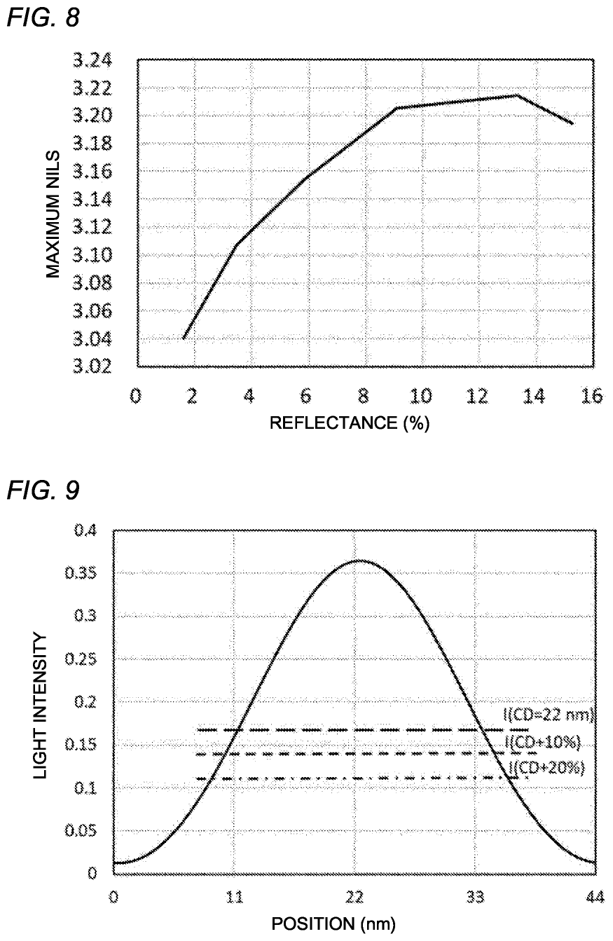

It is investigated whether side lobes generated in a large pattern within scribe lines are transferred when the EUV light reflectance is 13%. The material of the phase shift film is a Ru80Cr20 alloy, and the film thickness is 45 nm. FIG. 9 shows a cross-sectional view of light intensity on a wafer having a 22 nm dense hole pattern (HP) present in a chip. The light intensity I at CD=22 nm is 0.17, the light intensity I at CD=22 nm+10% is 0.14, and the light intensity I at CD=22 nm+20% is 0.11. The light intensity is a relative value when the intensity of incident light is set to 1.

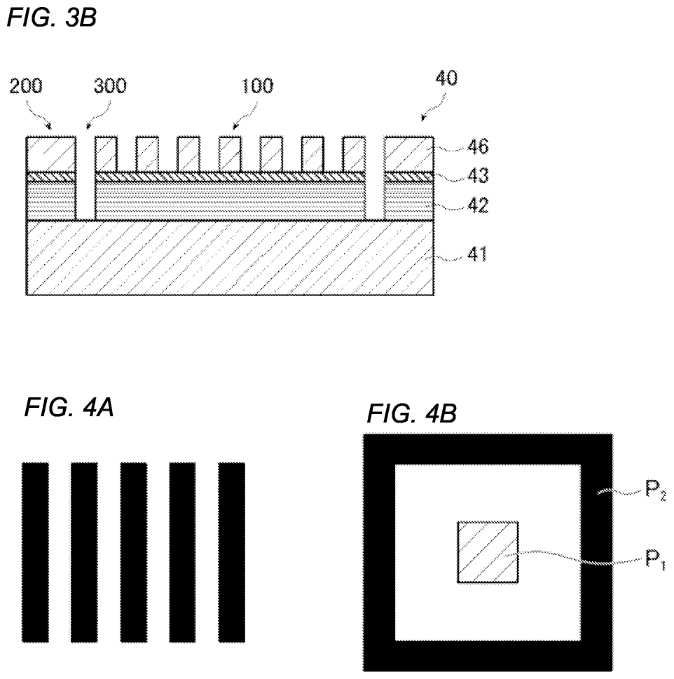

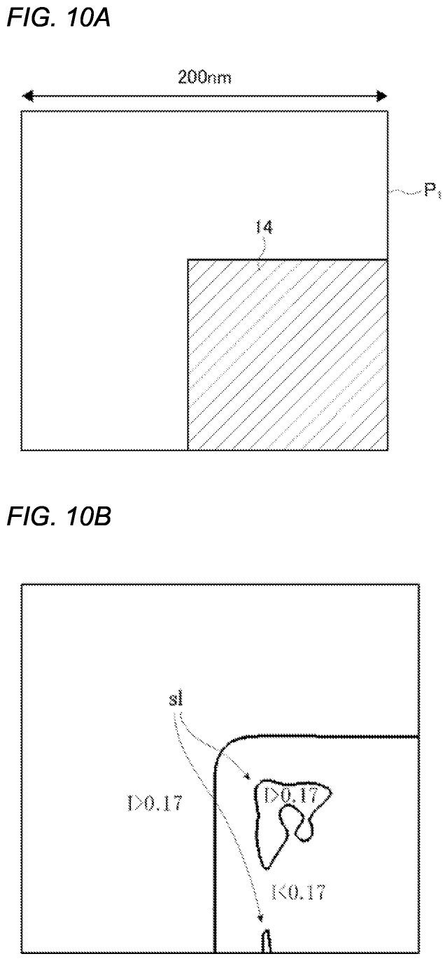

A large pattern such as alignment marks shown in FIG. 4A and overlay marks shown in in FIG. 4B is present within the scribe lines. Side lobes are most likely to generate at a corner of the large pattern, as shown in FIG. 10A. FIG. 10A shows, as the large pattern, a pattern P₁ as the overlay pattern shown in FIG. 4B. FIG. 10B shows a result of simulating a light intensity distribution on the wafer. FIG. 10B shows the light intensity distribution on the wafer around the corner of the pattern P₁. FIG. 10B shows a portion with the light intensity I>0.17 and a portion with the light intensity I<0.17 when transferring the 22 nm hole pattern HP present in a chip. A side lobe sl is generated at the corner position of the large pattern, and the light intensity I is more than 0.17. This portion is transferred to the resist.

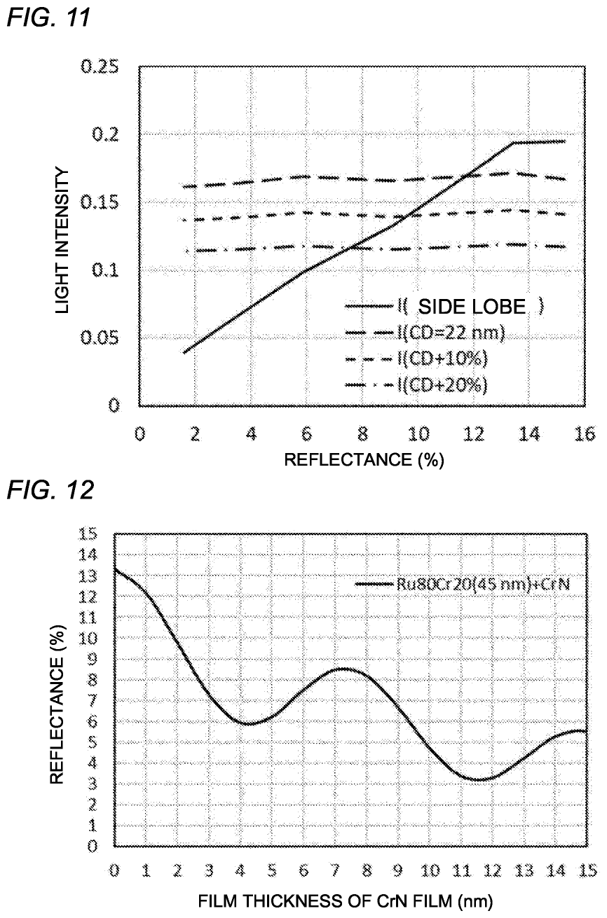

In order not to transfer side lobes of a large pattern, how much the reflectance should be lowered has been investigated. FIG. 11 is a diagram showing a relationship between the EUV light reflectance and side lobe light intensity. In FIG. 11, the side lobe light intensity increases as the EUV light reflectance increases. When CD+20% is taken as an exposure amount margin, the reflectance is required to be less than 7% in order to prevent the side lobes.

In order to lower the reflectance, a light shielding film 37 is provided on an absorber film 36 in a reflective mask 30 in Patent Literature 1 shown in FIG. 2A and FIG. 2B. At this time, the reflectance at a wavelength of 13.5 nm when the surface of the light shielding film 37 is irradiated with EUV light is less than 0.5%. At this time, the total film thickness of the absorber film 36 and the light shielding film 37 is required to be 70 nm or more. With such a thick film, pattern formation by etching is difficult.

On the other hand, in order to prevent the transfer of side lobes of a large pattern, the EUV light reflectance should be less than 7%. Therefore, the transfer of side lobes can be prevented by providing a semi-light-shielding film on the phase shift film.

FIG. 12 is a graph showing a relationship between a film thickness of a CrN film and the EUV light reflectance when the CrN film is provided as a semi-light-shielding film on a Ru80Cr20 alloy phase shift film having a thickness of 45 nm. As seen from FIG. 12, the film thickness of the CrN film should be 4 nm in order to make the EUV light reflectance less than 7%. At this time, the total film thickness of the phase shift film and the semi-light-shielding film is 50 nm or less, and the pattern can be easily formed by etching.

As described above, the inventor of the present invention has found that the EUV light reflectance should be less than 7% in order to prevent side lobes in a large pattern.

For this purpose, a semi-light-shielding film having a film thickness of 10 nm or less may be formed on the phase shift film. Since the semi-light-shielding film is thin, pattern formation by etching is easy.

Hereinafter, a reflective mask blank according to the present invention and a reflective mask according to the present invention will be described with reference to the drawings.

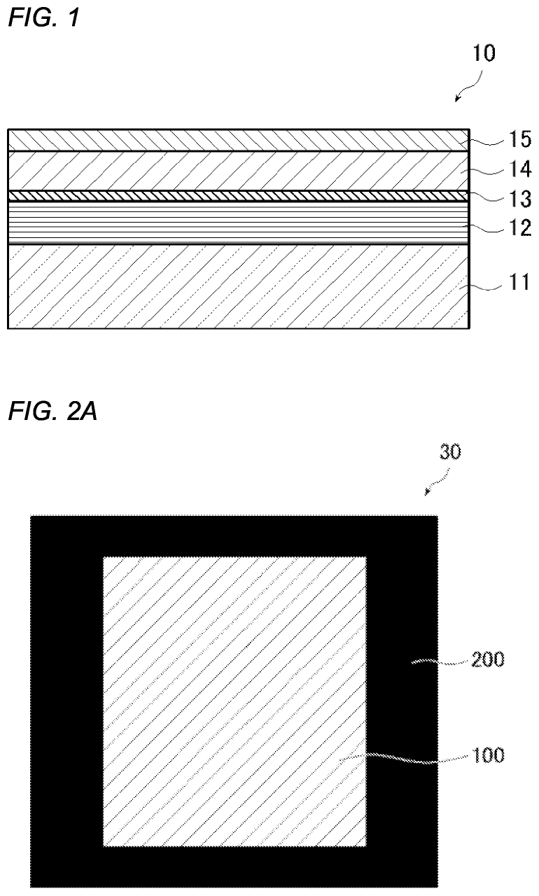

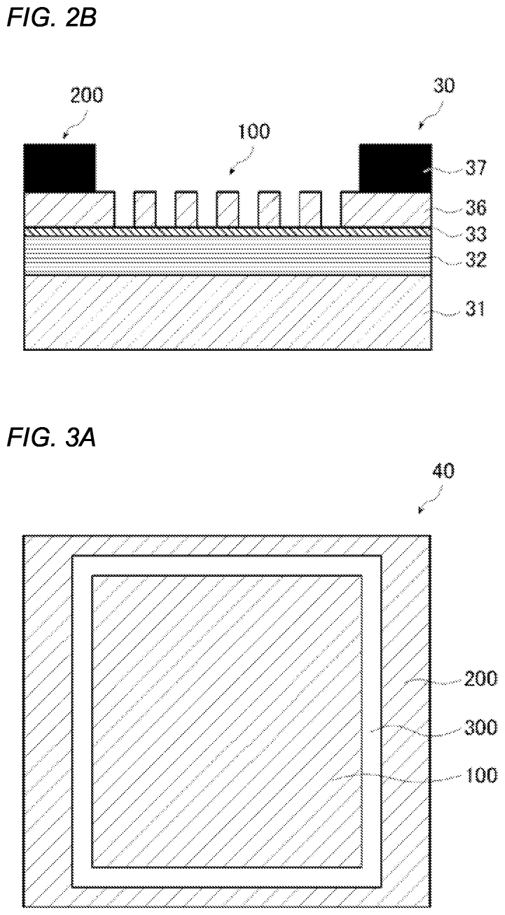

FIG. 1 is a schematic cross-sectional view showing one configuration example of the reflective mask blank according to the present invention. A reflective mask blank 10 shown in FIG. 1 includes, in order on a substrate 11, a multilayer reflective film 12 that reflects EUV light, a protective film 13 for the multilayer reflective film 12, a phase shift film 14 that shifts a phase of the EUV light, and a semi-light-shielding film 15 that shields the EUV light. However, in the reflective mask blank according to the present invention, only the substrate 11, the multilayer reflective film 12, the phase shift film 14, and the semi-light-shielding film 15 are essential in the configuration shown in FIG. 1, and the protective film 13 is an optional component.

The protective film 13 for the multilayer reflective film 12 is a layer provided for the purpose of protecting the multilayer reflective film 12 during pattern formation of the phase shift film 14.

Hereinafter, individual components of the reflective mask blank 10 will be described.

(Substrate)

The substrate 11 preferably has a small coefficient of thermal expansion. A substrate having a smaller coefficient of thermal expansion can prevent distortion of a pattern formed on a phase shift film due to heat during exposure to EUV light. Specifically, the coefficient of thermal expansion of the substrate is preferably 0±0.05×10⁻⁷/° C., and more preferably 0±0.03×10⁻⁷/° C. at 20° C.

As a material having a small coefficient of thermal expansion, for example, a SiO₂—TiO₂-based glass can be used. The SiO₂—TiO₂-based glass is preferably a silica glass containing 90 mass % to 95 mass % of SiO₂ and 5 mass % to 10 mass % of TiO₂. When the content of TiO₂ is 5 mass % to 10 mass %, the coefficient of linear expansion near room temperature is substantially zero, and a dimensional change is less likely to occur near room temperature. The SiO₂—TiO₂-based glass may contain minor components other than SiO₂ and TiO₂.

A first main surface of the substrate 11 on which the multilayer reflective film 12 is laminated preferably has high surface smoothness. The surface smoothness of the first main surface can be evaluated by surface roughness. The surface roughness of the first main surface is preferably 0.15 nm or less in terms of a root-mean-square roughness Rq. The surface smoothness can be measured with an atomic force microscope.

The first main surface is preferably surface-processed so as to have a predetermined flatness. This is because the reflective mask provides high pattern transfer accuracy and position accuracy. The substrate preferably has a flatness of 100 nm or less, more preferably 50 nm or less, and still more preferably 30 nm or less in a predetermined region (e.g., a 132 mm×132 mm region) of the first main surface.

In addition, the substrate 11 preferably has resistance to a cleaning solution for cleaning a reflective mask blank and a reflective mask after pattern formation.

Further, the substrate 11 preferably has high rigidity in order to prevent deformation due to film stress of films (such as the multilayer reflective film 12 and the phase shift film 14) formed on the substrate. For example, the substrate 11 preferably has a high Young's modulus of 65 GPa or more.

(Multilayer Reflective Film)

The multilayer reflective film 12 has a high reflectance with respect to EUV light. Specifically, when the EUV light is incident on the surface of the multilayer reflective film at an incident angle of 6°, the maximum value of the EUV light reflectance is preferably 60% or more, and more preferably 65% or more. Similarly, even when the protective film 13 is laminated on the multilayer reflective film 12, the maximum value of the EUV light reflectance is preferably 60% or more, and more preferably 65% or more.

The multilayer reflective film 12 is a multilayer film in which a plurality of layers, each layer including elements having different refractive indices as a main component, are periodically laminated. The multilayer reflective film is generally formed by alternately laminating, from the substrate side, a plurality of high refractive index films showing a high refractive index with respect to EUV light and low refractive index films showing a low refractive index with respect to EUV light.

The multilayer reflective film 12 may be obtained by lamination for a plurality of cycles with one cycle having a laminated structure in which a high refractive index film and a low refractive index film are laminated in this order from the substrate side, or may be obtained by lamination in a plurality of cycles with one cycle having a laminated structure in which a low refractive index film and a high refractive index film are laminated in this order. In this case, it is preferable that the outermost layer (uppermost layer) of the multilayer reflective film is a high refractive index film. Since the low refractive index film is easily oxidized, when the low refractive index film is the uppermost layer of the multilayer reflective film, the reflectance of the multilayer reflective film may decrease.

A film containing Si can be used as the high refractive index film. As the material containing Si, in addition to elemental Si, a Si compound containing Si and one or more selected from the group consisting of B, C, N, and O can be used. By using a high refractive index film containing Si, a reflective mask having an excellent EUV light reflectance can be obtained. A metal selected from the group consisting of Mo, Ru, Rh, and Pt, or an alloy thereof can be used as the low refractive index film. In the reflective mask blank according to the present invention, it is preferable that the low refractive index film is a Mo layer and the high refractive index film is a Si layer. In this case, when a high refractive index film (Si film) is used as the uppermost layer of the multilayer reflective film, a silicon oxide layer containing Si and O is formed between the uppermost layer (Si film) and the protective film 13 to improve the cleaning resistance of the reflective mask blank.

The film thickness and the cycle of the layer constituting the multilayer reflective film 12 can be appropriately selected depending on the film material used, the EUV light reflectance required for the multilayer reflective film 12, the wavelength of the EUV light (exposure wavelength), and the like. For example, when the multilayer reflective film 12 has a maximum value of the EUV light reflectance of 60% or more, a Mo/Si multilayer reflective film in which low refractive index films (Mo layers) and high refractive index films (Si layers) are alternately laminated for 30 to 60 cycles is preferably used. In order to obtain a high reflectance, the film thickness of one cycle of the Mo/Si multilayer film is preferably 6.0 nm or more, and more preferably 6.5 nm or more. In order to obtain a high reflectance, the film thickness of one cycle of the Mo/Si multilayer film is preferably 8.0 nm or less, and more preferably 7.5 nm or less.

Each of layers constituting the multilayer reflective film 12 can be formed to a desired thickness by using a known deposition method such as a magnetron sputtering method or an ion beam sputtering method. For example, when a multilayer reflective film is prepared using an ion beam sputtering method, ion particles are supplied from an ion source to a target of a high refractive index material and a target of a low refractive index material. When the multilayer reflective film 12 is a Mo/Si multilayer reflective film, a Si layer having a predetermined film thickness is formed on the substrate by an ion beam sputtering method by first using, for example, a Si target. Thereafter, a Mo layer having a predetermined film thickness is formed by using a Mo target. A Mo/Si multilayer reflective film is formed by laminating 30 to 60 cycles of the Si layer and the Mo layer as one cycle.

(Protective Film)

The protective film 13 protects the multilayer reflective film by preventing damage due to etching on the surface of the multilayer reflective film 12 when the phase shift film 14 is etched (generally dry-etched) to form a pattern during the production of a reflective mask, which will be described later. In addition, the protective film protects the multilayer reflective film from a cleaning solution when a resist film remaining on the reflective mask after etching is removed with the cleaning solution and the reflective mask is cleaned. Therefore, the obtained reflective mask has a good reflectance for EUV light.

FIG. 1 shows the case where the protective film 13 is one layer, but the protective film may be a plurality of layers.

As a material for forming the protective film 13, a substance that is not easily damaged by etching when the phase shift film 14 is etched is selected. Examples of the substance satisfying this condition include: a Ru-based material such as elemental metal of Ru, a Ru alloy containing Ru and one or more metals selected from the group consisting of Si, Ti, Nb, Rh, Ta, and Zr, and a nitride containing nitrogen in Ru alloys; elemental metals of Cr, Al, and Ta, and a nitride containing nitrogen in these; and SiO₂, Si₃N₄, Al₂O₃, and a mixture thereof. Among these, an elemental metal of Ru, a Ru alloy, CrN and SiO₂ are preferred. An elemental metal of Ru and a Ru alloy are particularly preferred because they are difficult to be etched by a gas containing no oxygen and function as an etching stopper during etching of the phase shift film 14.

When the protective film 13 is formed of a Ru alloy, the Ru content in the Ru alloy is preferably 30 at % or more and less than 100 at %. When the Ru content is within the above range, in the case where the multilayer reflective film 12 is a Mo/Si multilayer reflective film, diffusion of Si from the Si film in the multilayer reflective film 12 to the protective film 13 can be prevented. In addition, the protective film 13 functions as an etching stopper during etching of the phase shift film 14 while sufficiently ensuring the EUV light reflectance. Further, it is possible to improve the cleaning resistance of the reflective mask and prevent deterioration of the multilayer reflective film 12 over time.

The film thickness of the protective film 13 is not particularly limited as long as it can function as the protective film 13. From the viewpoint of maintaining the EUV light reflectance reflected by the multilayer reflective film 12, the film thickness of the protective film 13 is preferably 1 nm to 8 nm, more preferably 1.5 nm to 6 nm, and still more preferably 2 nm to 5 nm.

(Phase Shift Film)

The use of the phase shift film 14 improves the contrast of an optical image on the wafer and increases the exposure margin. The effect depends on the EUV light reflectance, as shown in FIG. 8, which shows the relationship between the EUV light reflectance and the maximum NILS. In order to obtain a sufficient phase shift effect, the phase shift film 14 has an EUV light reflectance of 9% or more and less than 15%, and preferably 9% or more and 13% or less.

In addition, the phase shift film 14 preferably has a phase shift amount of EUV light of 210 degrees or more and 250 degrees or less, and more preferably 220 degrees or more and 240 degrees or less.

In addition to the above properties, the phase shift film 14 is required to have desired properties such as being easily etched and having high cleaning resistance to a cleaning solution. A material for forming the phase shift film 14 is preferably a Ru-based material such as a Ru oxide, a Ru oxynitride, a Ru alloy containing Ru and one or more metal selected from the group consisting of Cr, Au, Pt, Re, Hf, Ti, and Si, an oxide containing oxygen in a Ru alloy, a nitride containing nitrogen in a Ru alloy, and an oxynitride containing oxygen and nitrogen in a Ru alloy. In the Ru alloy, an alloy of Ru and Cr, particularly an alloy in which the atomic ratio of Ru and Cr is 60:40 to 80:20, is preferred since the NILS is increased and the phase shift effect can be maximized.

When the material for forming the phase shift film 14 is a Ru-based material, by containing at least one of oxygen and nitrogen, the oxidation resistance of the phase shift film 14 can be improved, and thus the stability over time is improved. Further, when the Ru-based material contains at least one of oxygen and nitrogen, the phase shift film 14 has an amorphous or microcrystalline structure. Accordingly, the surface smoothness and the flatness of the phase shift film 14 are improved. When the surface smoothness and the flatness of the phase shift film 14 are improved, the edge roughness of the phase shift film pattern is reduced and the dimensional accuracy thereof is improved.

Therefore, the material for forming the phase shift film 14 is more preferably a Ru oxide, a Ru oxynitride, an oxide containing oxygen in the above Ru alloy, a nitride containing nitrogen in the above Ru alloy, and an oxynitride containing oxygen and nitrogen in the above Ru alloy, and still more preferably a Ru oxide.

The phase shift film 14 may be a single layer film or a multilayer film composed of a plurality of films When the phase shift film 14 is a single layer film, the number of steps in producing the mask blank can be reduced, and the production efficiency can be improved.

When the phase shift film 14 is a multilayer film, by appropriately setting the optical constant and the film thickness of the layer on the upper layer side of the phase shift film 14, it can be used as an antireflection film when inspecting the phase shift film pattern using inspection light. Accordingly, the inspection sensitivity when inspecting the phase shift film pattern is improved.

The film thickness of the phase shift film 14 is preferably 20 nm or more and 60 nm or less. The optimum value of the film thickness differs depending on the refractive index of the phase shift film 14.

The phase shift film 14 can be formed by using known deposition method such as a magnetron sputtering method and an ion beam sputtering method. For example, when forming a Ru oxide film as the phase shift film by using a magnetron sputtering method, the phase shift film can be formed by a sputtering method using a Ru target and an Ar gas and an oxygen gas.

The phase shift film 14 made of a Ru-based material can be etched by dry etching using an oxygen gas or a mixed gas containing an oxygen gas and a halogen-based gas (chlorine-based gas, fluorine-based gas) as an etching gas.

(Semi-Light-Shielding Film)

Since the phase shift film 14 has a high reflectance, side lobes are generated around the pattern in the light intensity distribution on the wafer during exposure. The light intensity of the side lobes increases with the size of the pattern, and side lobes in a large pattern may be transferred onto the resist on the wafer. It is effective to provide the semi-light-shielding film 15 in a scribe line region in order to prevent the side lobes in a large pattern within the scribe line. In order to prevent the transfer of the side lobes in a large pattern within the scribe line onto the resist, the semi-light-shielding film 15 preferably has an EUV light reflectance of less than 7%.

Unlike the light shielding film 37 in Patent Literature 1, the semi-light-shielding film 15 does not have an EUV light reflectance of less than 0.5%, and is sufficient to have an EUV light reflectance of less than 7%.

The semi-light-shielding film 15 is required to be easily patterned by etching. Therefore, the film thickness of the semi-light-shielding film 15 is preferably as thin as possible as long as the EUV light reflectance is less than 7%. The film thickness of the semi-light-shielding film 15 is preferably 10 nm or less, and more preferably 5 nm or less. In order to make the EUV light reflectance less than 7%, the film thickness of the semi-light-shielding film 15 is preferably 3 nm or more.

In order to obtain a phase shift effect during production of the reflective mask, it is necessary to remove the semi-light-shielding film 15 on the phase shift film 14 by etching in a chip region in the reflective mask. During this etching, the phase shift film 14 is required to be hardly influenced.

A Cr-based material such as Cr, CrO, CrN, and CrON can be used as a material for forming the semi-light-shielding film 15 that satisfies the above conditions. These Cr-based materials can be easily removed by wet etching. As an etching solution, for example, cerium ammonium nitrate can be used.

When the material for forming the semi-light-shielding film 15 is a Cr-based material, by containing at least one of oxygen and nitrogen, the oxidation resistance of the semi-light-shielding film 15 can be improved, and thus the stability over time is improved. Further, when the Cr-based material contains at least one of oxygen and nitrogen, the semi-light-shielding film 15 has an amorphous or microcrystalline structure. Accordingly, the surface smoothness and the flatness of the semi-light-shielding film 15 are improved. When the surface smoothness and the flatness of the semi-light-shielding film 15 are improved, the edge roughness of the semi-light-shielding film pattern is reduced and the dimensional accuracy thereof is improved.

Therefore, when the material for forming the semi-light-shielding film 15 is a Cr-based material, CrO, CrN, and CrON are preferred.

In addition, a Ta-based compound such as Ta, TaO, TaN, and TaON can be used as the semi-light-shielding film 15. These Ta-based materials can be easily removed by dry etching using a fluorine-based gas as an etching gas. When the material for forming the semi-light-shielding film 15 is a Ta-based material, by containing at least one of oxygen and nitrogen, the oxidation resistance of the semi-light-shielding film 15 can be improved, and thus the stability over time is improved. Further, when the Ta-based material contains at least one of oxygen and nitrogen, the semi-light-shielding film 15 has an amorphous or microcrystalline structure. Accordingly, the surface smoothness and the flatness of the semi-light-shielding film 15 are improved. When the surface smoothness and the flatness of the semi-light-shielding film 15 are improved, the edge roughness of the semi-light-shielding film pattern is reduced and the dimensional accuracy thereof is improved.

Therefore, when the material for forming the semi-light-shielding film 15 is a Ta-based material, TaO, TaN, and TaON are preferred.

The reflective mask blank 10 according to the present invention may include functional films known in the field of EUV mask blanks in addition to the multilayer reflective film 12, the protective film 13, the phase shift film 14, and the semi-light-shielding film 15.

(Back Conductive Film)

The reflective mask blank 10 according to the present invention may include a back conductive film for an electrostatic chuck on a second main surface of the substrate 11 opposite to the side on which the multilayer reflective film 12 is laminated. The back conductive film is required to have a low sheet resistance as properties. The sheet resistance of the back conductive film is preferably, for example, 200 Ω/square or less.

As a material of the back conductive film, for example, a metal such as Cr or Ta, or an alloy or compound containing at least one of Cr and Ta can be used. As the compound containing Cr, a Cr-based material containing Cr and one or more selected from the group consisting of B, N, O, and C can be used. Examples of the Cr-based material include CrN, CrON, CrCN, CrCON, CrBN, CrBON, CrBCN, and CrBOCN. As the compound containing Ta, a Ta-based material containing Ta and one or more selected from the group consisting of B, N, O, and C can be used. Examples of the Ta-based material include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, and TaSiCON.

The film thickness of the back conductive film is not particularly limited as long as it satisfies the function for electrostatic chuck, and is, for example, 10 nm to 400 nm. The back conductive film can also provide stress adjustment on the second main surface side of the reflective mask blank. That is, the back conductive film can adjust to flatten the reflective mask blank by balancing stresses from various layers formed on the first main surface side.

### <Reflective Mask>

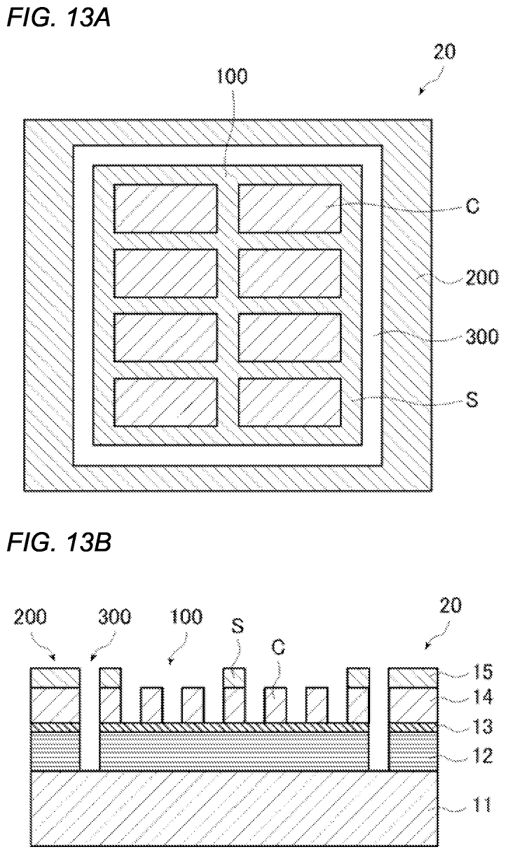

Next, a reflective mask obtained using the reflective mask blank shown in FIG. 1 will be described. FIG. 13A and FIG. 13B show diagrams showing one configuration example of the reflective mask according to the present invention. FIG. 13A is a plan view, and FIG. 13B is a schematic cross-sectional view.

In an exposure frame region 300 in a reflective mask 20, the multilayer reflective film 12, the protective film 13, the phase shift film 14, and the semi-light-shielding film 15 are removed, and the surface of the substrate 11 is exposed. Accordingly, overlapping light of adjacent shots is almost completely prevented.

An exposure region 100 in the reflective mask 20 has chip C regions and a scribe line S region. On the chip C regions, the semi-light-shielding film 15 is removed and the phase shift film 14 is exposed. Accordingly, for a fine pattern in the chip C regions, the phase shift effect improves the contrast of the optical image and increases the exposure margin.

The scribe line S region has the semi-light-shielding film 15. Therefore, for a large pattern within the scribe line, the light intensity of the side lobes is reduced, and the transfer onto the resist is prevented.

### <Method for Producing Reflective Mask>

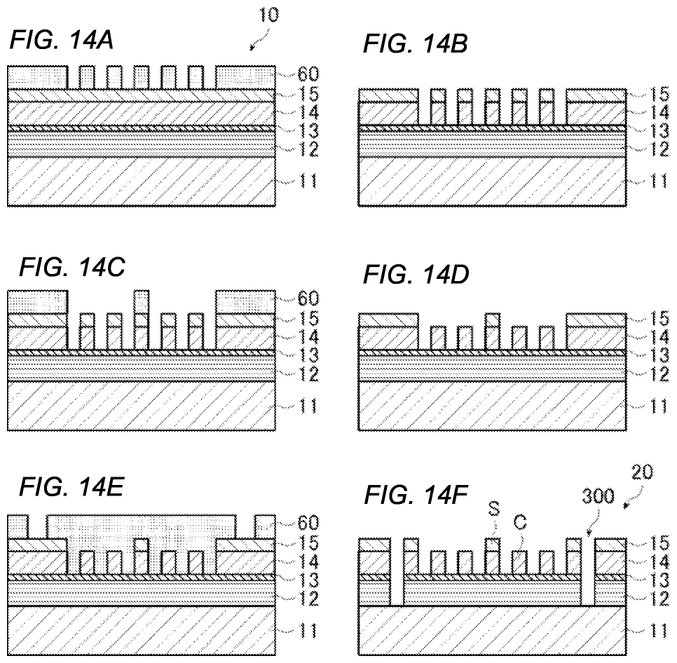

An example of a method for producing the reflective mask 20 in FIG. 13A and FIG. 13B will be described. FIG. 14A to FIG. 14F are diagrams showing a procedure for producing the reflective mask 20.

First, as shown in FIG. 14A, the reflective mask blank 10 is coated with a resist film, exposed, and developed to form a resist 60 pattern corresponding to a fine pattern of the chip C region and a pattern of the scribe line S region.

Next, as shown in FIG. 14B, the semi-light-shielding film 15 and the phase shift film 14 are dry-etched by using a resist pattern as a mask to form a semi-light-shielding film 15 pattern and a phase shift film 14 pattern. In FIG. 14B, the resist pattern is removed.

Next, as shown in FIG. 14C, the reflective mask blank is coated with a resist film, exposed, and developed to form a resist 60 pattern corresponding to the scribe line region.

Thereafter, as shown in FIG. 14D, using a resist pattern as a mask, the semi-light-shielding film 15 in the chip region is removed by wet etching or dry etching.

Next, as shown in FIG. 14E, the reflective mask blank is coated with a resist film, exposed, and developed to form a resist 60 pattern corresponding to a region other than the exposure frame region. Thereafter, as shown in FIG. 14F, dry etching is performed in the exposure frame region 300 by using a resist pattern as a mask until the surface of the substrate 11 is exposed. In this way, the reflective mask 20 shown in FIG. 13A and FIG. 13B can be produced.

### EXAMPLES

The present invention will be described in more detail below using Examples, but the present invention is not limited to these Examples. Among Examples 1 to 4, Example 1 is Comparative Example, and Examples 2 to 4 are Working Examples.

### Example 1

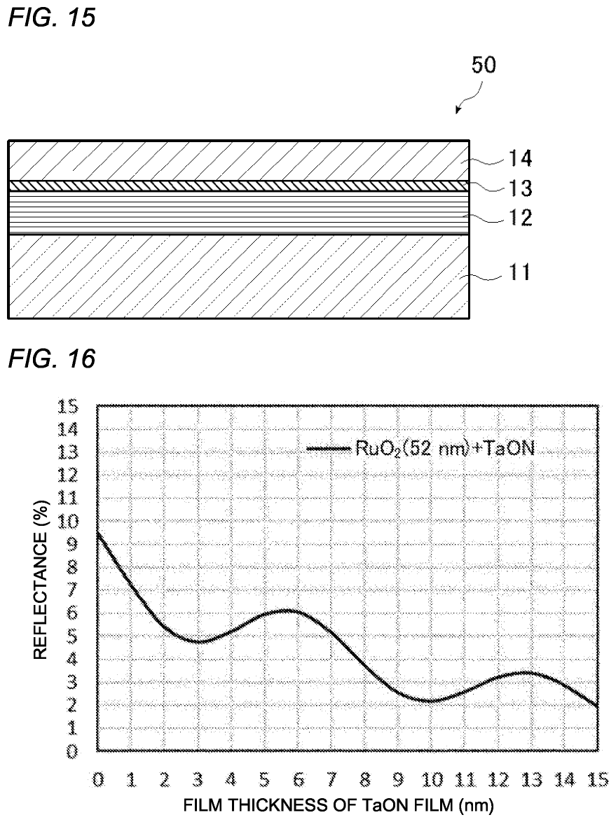

In Example 1, a reflective mask blank 50 shown in FIG. 15 was produced.

As a substrate 11 for deposition, a SiO₂—TiO₂-based glass substrate (outer shape: about 152 mm square, thickness: about 6.3 mm) was used. The coefficient of thermal expansion of the glass substrate was 0.02×10⁻⁷/° C. The glass substrate was polished to obtain a smooth surface having a surface roughness of 0.15 nm or less in terms of a root-mean-square roughness Rq and a flatness of 100 nm or less. A Cr layer having a thickness of about 100 nm was formed on the back surface of the glass substrate by using a magnetron sputtering method to form a back conductive film for an electrostatic chuck. The sheet resistance of the Cr layer was about 100 Ω/square. After fixing the glass substrate using the Cr film, alternately forming a Si film and a Mo film on the surface of the glass substrate using an ion beam sputtering method was repeated for 40 cycles. The film thickness of the Si film was about 4.5 nm, and the film thickness of the Mo film was about 2.3 nm. Accordingly, a multilayer reflective film 12 having a total film thickness of about 272 nm ((Si film: 4.5 nm+Mo film: 2.3 nm)×40) was formed. Thereafter, a Ru layer (film thickness: about 2.5 nm) was formed on the multilayer reflective film 12 using an ion beam sputtering method to form a protective film 13.

Next, a phase shift film 14 made of a RuCr film was formed on the protective film 13 by using a magnetron sputtering method. An Ar gas was used as the sputtering gas. Two kinds of targets, Ru and Cr, were used for sputtering. By adjusting the input power to the Ru target and the input power to the Cr target, a film having an atomic ratio of 80:20 of Ru:Cr was formed with a film thickness of 45 nm. The phase shift film 14 had an EUV light reflectance of 13%.

The film thickness was measured by an X-ray reflectance method (XRR) using an X-ray diffractometer. The reflectance was measured using an EUV reflectometer for mask blanks.

The reflective mask blank 50 in FIG. 15 does not include a semi-light-shielding film. Therefore, when producing a reflective mask using the reflective mask blank 50, a large pattern such as an alignment mark within the scribe line is transferred with side lobes during exposure.

### Example 2

In Example 2, the reflective mask blank 10 shown in FIG. 1 was produced.

The same procedure as in Example 1 was performed until the phase shift film 14 was formed. A semi-light-shielding film 15 made of a CrN film was formed on the phase shift film 14 by using a magnetron sputtering method. A mixed gas containing an Ar gas and a nitrogen gas was used as the sputtering gas. A Cr target was used for sputtering. A CrN film was formed with a thickness of 4 nm. The semi-light-shielding film 15 had an EUV light reflectance of 6%.

When producing the reflective mask 20 shown in FIG. 13A and FIG. 13B using the reflective mask blank 10, since the scribe line S region has the semi-light-shielding film 15, it is possible to prevent side lobes from being transferred during exposure.

### Example 3

In Example 3, the reflective mask blank 10 shown in FIG. 1 was produced. In Example 3, a RuO₂ film was used as the phase shift film 14 and a TaON film was used as the semi-light-shielding film 15. FIG. 16 shows the result of simulating the relationship between the film thickness of the TaON film and the EUV light reflectance.

The same procedure as in Example 1 was performed until the protective film 13 was formed. A phase shift film 14 made of a RuO₂ film was formed on the protective film 13 by using a magnetron sputtering method. A mixed gas containing an Ar gas and an oxygen gas was used as the sputtering gas. A Ru target was used for sputtering. A RuO₂ film having a film thickness of 52 nm was formed as the phase shift film 14. The phase shift film 14 had an EUV light reflectance of 9%.

A semi-light-shielding film 15 made of a TaON film was formed on the phase shift film 14 by using a magnetron sputtering method. A mixed gas containing an Ar gas, an oxygen gas, and a nitrogen gas was used as the sputtering gas. A Ta target was used for sputtering. A TaON film having a film thickness of 3 nm was formed as the semi-light-shielding film 15. The semi-light-shielding film 15 had an EUV light reflectance of 5%.

When producing the reflective mask 20 shown in FIG. 13A and FIG. 13B using the reflective mask blank 10, since the scribe line S region has the semi-light-shielding film 15, it is possible to prevent side lobes from being transferred during exposure.

### Example 4

In Example 4, the reflective mask blank prepared in Example 3 was used to produce the reflective mask shown in FIG. 13A and FIG. 13B.

In FIG. 13A and FIG. 13B, the size of each chip C is 40 mm in the X direction and 32 mm in the Y direction. This dimension is the value on the mask, and is reduced to ¼ during wafer transfer, resulting in 10 mm in the X direction and 8 mm in the Y direction. The width of the scribe line S is 200 μm on the mask (50 μm on the wafer). When eight chips C are disposed as shown in FIG. 13A and FIG. 13B, the size of the exposure region 100 including the scribe line S is 80.4 mm in the X direction and 128.8 mm in the Y direction on the mask (20.1 mm in the X direction and 32.2 mm in the Y direction on the wafer). An exposure frame having a width of 1 mm is disposed outside the exposure region 100.

The procedure for producing the reflective mask followed the procedure in FIG. 14A to FIG. 14F. First, a resist was applied, and the fine pattern in the chip region and the pattern within the scribe line were exposed by EB. After developing the resist, the semi-light-shielding film 15 made of a TaON film and the phase shift film 14 made of a RuO₂ film were dry-etched using a resist 60 pattern as a mask. A fluorine-based gas was used for etching the TaON film, and a mixed gas containing chlorine and oxygen was used for etching the RuO₂ film. After dry etching, the resist film was removed by ashing and cleaning.

Thereafter, a resist was applied and the chip region was exposed. A laser exposure machine was used because the exposure region was large. The resist 60 pattern after development was exposed over the entire surface of the chip region. The semi-light-shielding film 15 made of a TaON film in the chip region was removed by dry etching using a fluorine-based gas.

A resist was applied again, and the exposure frame region 300 was laser-exposed. The etching in the exposure frame region 300 was physical dry etching with a high bias power to remove up to the multilayer reflective film, thereby exposing the surface of the substrate. In this way, the reflective mask 20 shown in FIG. 13A and FIG. 13B was obtained.

Although the present invention has been described in detail with reference to specific embodiments, it is apparent to those skilled in the art that various changes and modifications can be made without departing from the spirit and scope of the present invention.

The present application is based on a Japanese Patent Application (No. 2020-148984) filed on Sep. 4, 2020, the contents of which are incorporated herein by reference.

### REFERENCE SIGNS LIST

10: EUV mask blank

11: Substrate

12: Multilayer reflective film

13: Protective film

14: Phase shift film

15: semi-light-shielding film

20: EUV mask

30: EUV mask

31: Substrate

32: Multilayer reflective film

33: Protective film

36: Absorber film

37: Light shielding film

100: Exposure region

200: Non-exposure region

40: EUV mask

41: Substrate

42: Multilayer reflective film

43: Protective film

46: Absorber film

60: Resist

100: Exposure region

200: Non-exposure region

300: Exposure frame region

C: Chip

P₁: Upper layer pattern

P₂: Lower layer pattern

HP: Hole pattern

sl: Side lobe

S: Scribe line

1. A reflective mask blank comprising:
a substrate; and
a multilayer reflective film configured to reflect EUV light; a phase shift film configured to shift a phase of the EUV light; and a semi-light-shielding film configured to shield the EUV light, which are formed on the substrate in this order, wherein
a reflectance at a wavelength of 13.5 nm when a surface of the semi-light-shielding film is irradiated with the EUV light is less than 7%, and
a reflectance at a wavelength of 13.5 nm when a surface of the phase shift film is irradiated with the EUV light is 9% or more and less than 15%.

2. The reflective mask blank according to claim 1, wherein the semi-light-shielding film has a film thickness of 3 nm or more and 10 nm or less.

3. The reflective mask blank according to claim 1, wherein the phase shift film has a phase shift amount of EUV light of 210 degrees or more and 250 degrees or less.

4. The reflective mask blank according to claim 1, wherein the phase shift film is made of a Ru-based material comprising Ru.

5. The reflective mask blank according to claim 1, wherein the semi-light-shielding film is made of a Cr-based material comprising Cr or a Ta-based material comprising Ta.

6. The reflective mask blank according to claim 1, wherein the phase shift film has a film thickness of 20 nm or more and 60 nm or less.

7. The reflective mask blank according to claim 1, further comprising a protective film for the multilayer reflective film between the multilayer reflective film and the phase shift film.

8. A reflective mask obtained by forming a pattern comprising a chip region and a scribe line region on the semi-light-shielding film and the phase shift film of the reflective mask blank according to claim 1, wherein
the chip region in the pattern does not have the semi-light-shielding film on the phase shift film, and
the scribe line region in the pattern has the semi-light-shielding film on the phase shift film

9. The reflective mask according to claim 8, wherein
the pattern comprises an exposure frame region, and
the exposure frame region does not have the multilayer reflective film, the phase shift film, and the semi-light-shielding film, and a surface of the substrate is exposed.

10. A method for producing a reflective mask, comprising:
forming a pattern comprising a chip region and a scribe line region on the semi-light-shielding film and the phase shift film of the reflective mask blank according to claim 1;
removing the semi-light-shielding film in the chip region; and
etching the semi-light-shielding film, the phase shift film, and the multilayer reflective film in an exposure frame region until a surface of the substrate is exposed.
